(19) United States
(12) Patent Application Publication
(10) Pub. No.: US 2026/0044165 A1
(43) Pub. Date: Feb. 12, 2026

(54) SINGLE-ENDED INPUT BIAS ADAPTATION RECEIVER

(71) Applicant: MACOM Technology Solutions Holdings, Inc., Lowell, MA (US)

(72) Inventors: Heewon Suh, Seoul (KR); Ilhyun Cho, Yongin-si (KR); Kiwon Choi, Yongin-si (KR); Hyunbae Jin, Seoul (KR); Sebastien Jacquet, OPIO (FR); Kwangseok Han, Seongnam (KR)

(21) Appl. No.: 18/799,565

(22) Filed: Aug. 9, 2024

(51) Int. Cl. G05F 1/56; H03H 11/28; H04B 1/16

(52) U.S. Cl. CPC G05F 1/56; H03H 11/28; H04B 1/16

(57) ABSTRACT

Aspects of single-ended input bias adaptation receivers are described herein. An example receiver circuit with adaptive biasing includes an on-die termination network coupled to a single-ended receiver input and a potential equalizer coupled to the single-ended receiver input and the on-die termination network. The potential equalizer includes a biased voltage divider and an equalized bias node. The receiver circuit also includes a receive driver coupled to the equalized bias node and a feedback circuit loop coupled between the equalized bias node and a node in the biased voltage divider. The feedback circuit loop generates a current control signal, and the current control signal is injected into a node of the biased voltage divider. In that way, the feedback circuit loop adjusts a bias voltage at the equalized bias node based on the current control signal.

### BACKGROUND

The single-ended signaling interface is a relatively simple and commonly used interface for signal communications. In a single-ended signaling interface, a single wire or conductor is relied upon to carry a potential or voltage, which can vary over time to represent the information being communicated. The potential on the wire is compared against another reference voltage, often signal ground, to determine or decode information over time. Single-ended signaling can be distinguished from differential signaling. Differential signaling relies upon two balanced line conductors and the difference in voltages on the balanced line conductors over time for information coding and decoding.

For single-ended signaling interfaces between packaged integrated circuit (IC) devices, for example, the term on-die termination (ODT) refers to the use of on-die (e.g., or on-substrate) termination resistors for impedance matching the single-ended interfaces. The ODT approach can be contrasted with the use of termination resistors that are off-die and typically positioned outside of the IC packages.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Aspects of single-ended input bias adaptation receivers are described herein. An example receiver circuit with adaptive biasing includes an on-die termination network coupled to a single-ended receiver input and a potential equalizer coupled to the single-ended receiver input and the on-die termination network. The potential equalizer includes a biased voltage divider and an equalized bias node. The receiver circuit also includes a receive driver coupled to the equalized bias node and a feedback circuit loop coupled between the equalized bias node and a node in the biased voltage divider. The feedback circuit loop generates a current control signal, and the current control signal is injected into a node of the biased voltage divider. In that way, the feedback circuit loop adjusts a bias voltage at the equalized bias node based on the current control signal.

In other aspects, the potential equalizer further includes an inline resistor-capacitor (RC) network coupled to the single-ended receiver input, and the equalized bias node is positioned between the RC network and the biased voltage divider. The feedback circuit loop includes a difference amplifier, an analog-to-digital converter, and a digital-to-current converter in one example. The feedback circuit loop can also include a filter between the equalized bias node and the difference amplifier.

In still other aspects, the difference amplifier outputs a difference voltage based on a difference between a reference voltage and a bias voltage at the equalized bias node. The analog-to-digital converter converts the difference voltage from the difference amplifier to a digital difference value. In one case, the digital-to-current converter converts the digital difference value to a current control signal, and the current control signal is injected into a node of the biased voltage divider.

In some embodiments, the receiver circuit also includes a second single-ended receiver input, a second potential equalizer coupled to the second single-ended receiver input, a second feedback circuit loop coupled between the second equalized bias node and a second node in the second biased voltage divider, and a memory to store the digital difference value. The second the potential equalizer includes a second biased voltage divider and a second equalized bias node, and the second feedback circuit loop includes a second digital-to-current converter. The memory is configured to store the digital difference value and to provide the digital difference value to the second digital-to-current converter.

Another example receiver circuit includes a receiver input, a potential equalizer coupled to the receiver input, and a feedback circuit loop coupled between the equalized bias node and a node in the biased voltage divider. The potential equalizer includes a biased voltage divider and an equalized bias node. The feedback circuit loop generates a control signal, and the control signal is provided to a node of the potential equalizer. The feedback circuit loop adjusts a bias voltage at the equalized bias node based on the control signal.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1A illustrates a single-ended communications interface according to various aspects of the embodiments described herein.

FIG. 1B illustrates another single-ended communications interface according to various aspects of the embodiments described herein.

FIG. 2 illustrates example voltage potentials for a modulation scheme used in the communications interfaces shown in FIGS. 1A and 1B over a number of periods or cycles according to various aspects of the embodiments described herein.

FIG. 3 illustrates a single-ended communications interface including bias adaptation according to various aspects of the embodiments described herein.

FIG. 4 illustrates another single-ended communications interface including bias adaptation according to various aspects of the embodiments described herein.

FIG. 5 illustrates additional single-ended communications interfaces with bias adaptation according to various aspects of the embodiments described herein.

### DETAILED DESCRIPTION

Pulse-amplitude modulation (PAM) is a signal modulation technique in which information or data is encoded in the amplitude of the modulated output signal. PAM has been applied as an analog modulation scheme, although PAM modulation techniques have also been relied upon for the communication of digital data. Digital data can be communicated through a sequence of pulses in which data is encoded as a voltage potential, per period or cycle, over time. PAM demodulation can be performed by detecting the amplitude of the voltage potential each period or cycle. Higher-order PAM modulation schemes rely upon additional, and different, voltage potentials to distinguish among more values of encoded data. The use of higher-order PAM modulation schemes can be challenging due to the increased sensitivity to noise, which can lead to the need for equalizers, forward error correction, and related techniques to maintain suitable bit error rates.

Among other devices, certain memory devices are being designed to use PAM3 encoding or modulation in some cases. PAM3 modulation relies upon three level signaling (e.g., −1, 0, +1) for data encoding. PAM3 modulation transmits 1.5 bits per period or cycle, for 3 bits over two cycles. Some memory devices may be designed to shift between PAM3 encoding and other non-return-to-zero (NRZ) encoding modes based on bandwidth needs.

Single-ended signaling interfaces are used in a range of devices and applications. Memory devices, for example, often incorporate single-ended signaling interfaces for data bus (e.g., DQ) lines, among other interfaces. Memory devices can be mounted and electrically coupled to a printed circuit board (PCB), such as the PCB of a memory module or a motherboard.

The signal-ended data bus lines can be terminated using termination resistors on a memory module or motherboard, for example, which can improve impedance matching and help to reduce reflections on the signal lines. However, the use of termination resistors cannot prevent reflections resulting from stub lines, among other issues. On the other hand, on-die termination (ODT) refers to the use of on-die (e.g., or on-substrate) termination resistors for impedance matching single-ended interfaces. Among other benefits, the use of ODT can improve impedance matching, provide a more flexible approach for impedance matching, reduce the overall number of discrete components, and simplify the traces and contact pads on PCBs.

In single-ended signaling interfaces with ODT, the voltage potential levels of the signals being communicated can vary depending on the supply voltages of both the transmitter and the receiver. For PAM3 modulation over a single-ended signaling interface with ODT, as one example, the voltage levels for signaling (e.g., −1, 0, +1) or data encoding can vary depending on the supply voltages of both the transmitter and the receiver. Higher-order PAM modulation schemes can be more challenging to implement as compared to lower-order schemes, and the effects of supply voltage differences among the transmitter and the receiver can make the implementation even more challenging.

Aspects of single-ended input bias adaptation receivers are described herein. An example receiver circuit with adaptive biasing includes an on-die termination network coupled to a single-ended receiver input and a potential equalizer coupled to the single-ended receiver input and the on-die termination network. The potential equalizer includes a biased voltage divider and an equalized bias node. The receiver circuit also includes a receive driver coupled to the equalized bias node and a feedback circuit loop coupled between the equalized bias node and a node in the biased voltage divider. The feedback circuit loop generates a current control signal, and the current control signal is injected into a node of the biased voltage divider. In that way, the feedback circuit loop adjusts a bias voltage at the equalized bias node based on the current control signal.

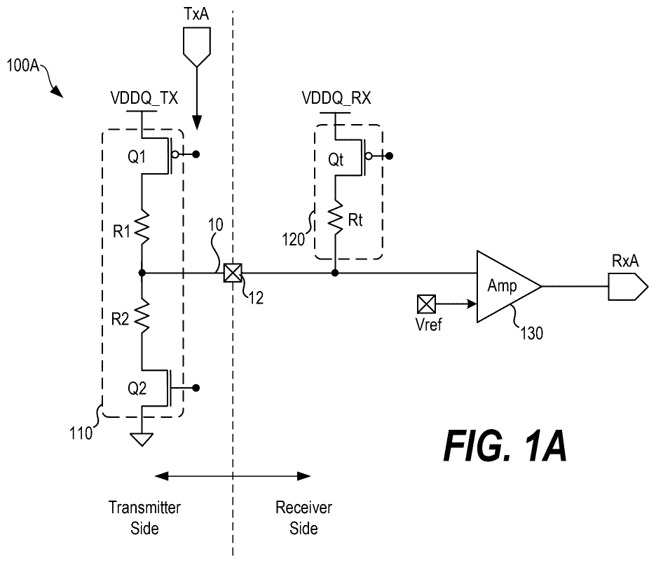

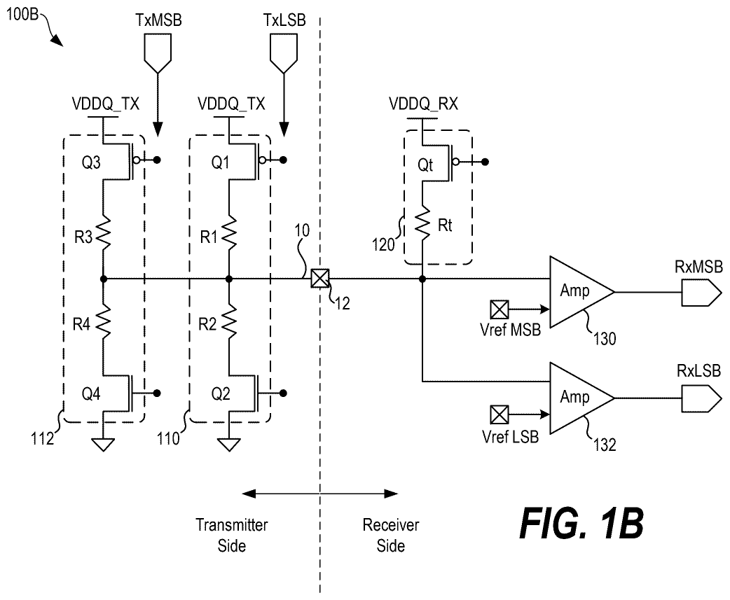

Turning to the drawings, FIG. 1A illustrates a single-ended communications interface 100A (also “interface 100A”) according to various aspects of the embodiments. The interface 100A includes a single-ended source-series-terminated (SST) transmit (TX) driver 110 (also “TX driver 100”), a termination network 120 for on-die termination (ODT), and a receive (RX) driver 130 (also “RX driver 130”). The interface 100A is implemented over a signal trace 10, which extends from a transmitter side to a receiver side and across a terminal 12. In practice, the signal trace 10 can be embodied as a signal trace extending on one or more PCBs, a conductor in one or more wires, or another conductor or combination thereof. The signal trace 10 can also extend through plated vias of PCBs, through pins or terminals of connectors, through pins or terminals of device packages, and other electrical components. The TX driver 100 is positioned on the transmitter side of the terminal 12, and the RX driver 130 is positioned on the receiver side of the terminal 12. In the interface 100A, the signal trace 10 also operates as a node between the TX driver 100 and the RX driver 130.

The interface 100A is provided as a representative example of a single-ended communications interface that may be used between a memory controller, system chipset, or other controller on the transmitter side and a memory device, such as a GDDR7 SDRAM device, on the receiver side. Thus, as one example, the TX driver 100 can be implemented on a first integrated circuit (IC) device in a first device package, and the termination network 120 and RX driver 130 can be implemented on second IC device in a second device package. The interface 100A is not exhaustively illustrated in FIG. 1A and may include additional components or features that are not shown. For example, the interface 100A can be part of a bidirectional single-ended communications interface, and both the transmitter and receiver sides can be implemented as transceivers. The concepts of bias adaptation and voltage potential equalization, as described herein, can be implemented in the interface 100A and the related interfaces described below. The concepts of bias adaptation and voltage potential equalization can also be implemented in other types of communications interfaces for a range of different devices. The concepts are not limited to use in single-ended communications interfaces or single-ended communications interfaces for memory devices.

The TX driver 100 is an example of an SST driver and includes a divider network of resistors R1 and R2 and a pair of field-effect transistors (FETs) Q1 and Q2. The transistor Q1 is implemented as P-channel FET, and the transistor Q2 is implemented as an N-channel FET in the example shown. The transistors Q1 and Q2 can be implemented in a range of different semiconductor materials and semiconductor manufacturing process techniques, such as complimentary metal-oxide semiconductor (CMOS) and related technologies. The drain of the transistor Q1 is coupled to a supply voltage VDDQ_TX for the transmitter side device. The source of the transistor Q1 is coupled to one end of the resistor R1. Another end of the resistor R1 is coupled to one end of the resistor R2. Another end of the resistor R2 is coupled to the drain of the transistor Q2, and the source of the transistor Q2 is coupled to ground. The TX driver 100 can be implemented as other types and arrangements of transistors and resistor divider networks in other cases. The gates of the transistors Q1 and Q2 can be driven by a TxA control signal, which is representative of one or more control signals for the gates of the transistors Q1 and Q2.

Overall, the TX driver 100 is designed and configured to control and drive the voltage potential on the signal trace 10 over time based on the logical value of TxA, as described in further detail below. The TX driver 100 operates in connection with the termination network 120 on the receiver side. The termination network 120 is an example of a network that can be relied upon for ODT of the interface 100A. The termination network 120 is representative in FIG. 1A. As shown, the termination network 120 includes a termination resistor Rt and a termination transistor Qt. The transistor Qt is coupled between a supply voltage VDDQ_RX for the receiver side device and the termination resistor Rt. The termination resistor Rt is coupled between the transistor Qt and the signal trace 10.

Although not illustrated, the termination network 120 can include a larger network of termination resistors and transistors, as would be understood in the field. The termination network 120, including the equivalent impedances of Rt and Qt can be configured and calibrated as part of an ODT process, as would also be understood in the field. An ODT calibration controller (not shown), can evaluate voltage drops in the termination network 120 against reference potentials and, as needed, modify or tailor the resistance of Rt, Qt, or both Rt, Qt, with coarser and finer tuning settings over time. The ODT calibration controller can tailor the impedance of the termination network 120 to achieve impedance matching and other benefits on the interface 100A.

The TX driver 100 on the transmitter side operates in connection with the termination network 120 on the receiver side, because the signal trace 10 is electrically coupled between the resistors R1 and R2 and to the termination network 120. A voltage divider is formed by the parallel combination of the termination network 120 and the resistor R1, on one side of the signal trace 10, and the resistor R2 on another side of the signal trace 10. The signal trace 10 serves as a type of node in the center of the voltage divider between the TX driver 100 and the termination network 120. The impedance of the termination network 120 can be steady and always present (e.g., the transistor Qt can be always on). The impedances of the R1 and R2 resistors can vary based on the design. Example resistances for the R1 and R2 resistors include 20Ω, 40Ω, 60Ω, 80Ω, 100Ω, or 120Ω each, and the R1 and R2 resistors can have the same or different resistances depending on the design.

In operation, TxA can drive a higher voltage potential on the signal trace 10 by turning Q1 on and Q2 off. With Q1 on and Q2 off, a higher voltage potential on the signal trace 10 will substantially result from a combination of the VDDQ_TX and VDDQ_RX supply voltages and the parallel combination of R1 and Rt. The TxA control signal can also drive a lower voltage potential on the signal trace 10 by turning Q1 off and Q2 on. With Q1 being off and Q2 on, a lower voltage potential on the signal trace 10 will substantially result from a combination of the VDDQ_RX supply voltage and the voltage divider circuit provided by Rt and R2.

Variations in the supply voltages used at the transmitter side and the receiver side can occur in single-ended interfaces with ODT. That is, the VDDQ_TX and VDDQ_RX supply voltages can be different depending on the implementation. The VDDQ_TX and VDDQ_RX supply voltages can also vary in some circumstances even in the same implementation and, possibly, over time. Thus, the voltage potential levels of the signals being communicated over the signal trace 10 can vary depending on the VDDQ_TX and VDDQ_RX supply voltages.

As examples, each of the VDDQ_TX and VDDQ_RX supply voltages can individually and separately range, such as between 1.6V to 1V, between 1.5V and 1.25V, between 1.35V and 1.3V, and between other voltage ranges. Example VDDQ_TX and VDDQ_RX supply voltages include 1.7V, 1.65V, 1.6V, 1.55V, 1.5V, 1.45V, 1.4V, 1.35V, 1.3V, 1.25V, 1.2V, 1.15V, 1.1V, 1.05V, and 1.0V, and other voltages can be relied upon.

The RX driver 130 can be implemented as a difference amplifier in one example. The RxA output of the RX driver 130 can be based on the difference in the voltage potential on the signal trace 10 and the Vref voltage, as shown in FIG. 1A. The RxA output can be provided as an input to additional slicing/logic circuitry (not shown) that is configured to discern the logical value(s) of the data that is communicated by the TX driver 100 over time. The RX driver 130 can also be implemented in other ways, such as a comparator, slicer, or other type of operational component in some cases.

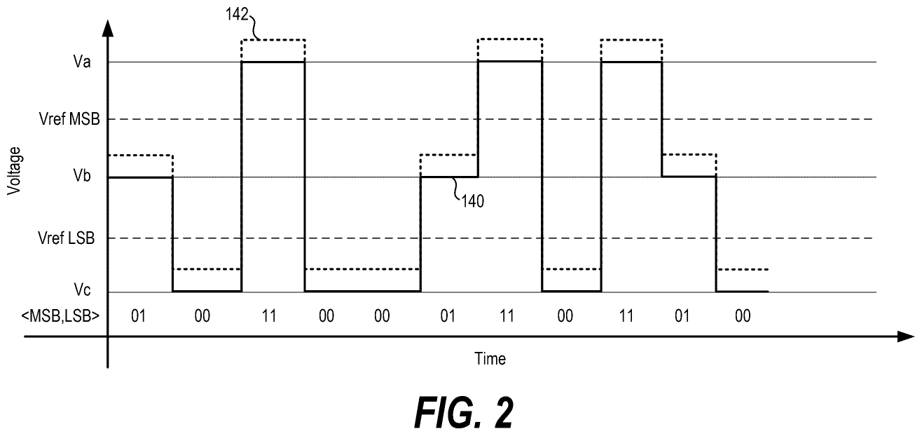

It can be difficult to design and optimize the RX driver 130 to accommodate a relatively wide range of VDDQ_TX and VDDQ_RX supply voltages. Particularly, the RxA output of the RX driver 130 will vary depending on the VDDQ_TX and VDDQ_RX supply voltages, unless Vref is modified to account for any differences in the VDDQ_TX and VDDQ_RX supply voltages. The issue can be particularly problematic if higher-order PAM modulation techniques are relied upon in the interface 100A, as described below with reference to FIG. 2.

FIG. 1B illustrates another single-ended communications interface 100A (also “interface 100B”) according to various aspects of the embodiments. The interface 100B includes the TX driver 100, a second TX driver 112, the termination network 120, the RX driver 130, and a second RX driver 132. The interface 100B is implemented over the signal trace 10, which extends from the transmitter side to the receiver side and across the terminal 12. The TX drivers 100 and 112 are positioned on the transmitter side of the terminal 12, and the RX drivers 130 and 132 are positioned on the receiver side of the terminal 12. The interface 100B in FIG. 1B is similar to the interface 100A shown in FIG. 1A, but the interface 100B includes the additional TX driver 112 and the additional RX driver 132 to facilitate the use of PAM3 modulation over the signal trace 10. Particularly, the additional TX driver 112 and RX driver 132 facilitate the additional voltage levels needed for signaling (e.g., −1, 0, +1) according to the PAM3 modulation scheme.

The TX driver 112 includes a divider network of resistors R3 and R4 and a pair of FETs Q3 and Q4. The transistor Q3 is implemented as P-channel FET, and the transistor Q4 is implemented as an N-channel FET in the example shown. The transistors Q3 and Q4 can be implemented in a range of different semiconductor materials and semiconductor manufacturing process techniques. The drain of the transistor Q3 is coupled to the supply voltage VDDQ_TX. The source of the transistor Q3 is coupled to one end of the resistor R3. Another end of the resistor R3 is coupled to one end of the resistor R4. Another end of the resistor R4 is coupled to the drain of the transistor Q4, and the source of the transistor Q4 is coupled to ground. The gates of the transistors Q3 and Q4 can be driven by a TxMSB control signal, which is representative of one or more control signals for the transistors Q3 and Q4 for the most significant bit for data transmission in the PAM3 modulation scheme. In the TX driver 110, the gates of the transistors Q1 and Q2 can be driven by a TxLSB control signal, which is representative of one or more control signals for the transistors Q1 and Q2 for the least significant bit for data transmission in the PAM3 modulation scheme. Example resistances for the R3 and R4 resistors include 20Ω, 40Ω, 60Ω, 80Ω, 100Ω, or 120Ω each, and the R3 and R4 resistors can have the same or different resistances depending on the design.

The TX drivers 100 and 112 operate in connection with the termination network 120 on the receiver side, because the signal trace 10 is electrically coupled between the resistors R1, R2, R3, and R4 and the termination network 120. Depending on the states of the Q1 and Q3 transistors (i.e., on/off, conducting or pinched off states), different voltage dividers can be formed by parallel combinations of the termination network 120 with the resistors R1, R3, or both R1 and R3. Depending on the states of the Q1 and Q3 transistors, different voltage dividers can be formed by the parallel combination of or individual resistances of the resistors R2 and R4.

In operation, the TxMSB and TxLSB control signals can direct the Q1-Q4 transistors in the TX drivers 100 and 112 to drive voltage potentials on the signal trace 10 for data communications using the PAM3 modulation scheme. The RX drivers 130 and 132 can be implemented as difference amplifiers. The output RxMSB of the RX driver 130 can be based on the difference in the voltage potential on the signal trace 10 and the Vref MSB voltage, as shown in FIG. 1B. The output RxLSB of the RX driver 132 can be based on the difference in the voltage potential on the signal trace 10 and the Vref LSB voltage, as shown in FIG. 1B. The RxMSB and RxLSB outputs can be provided as inputs to additional slicing/logic circuitry (not shown). The circuitry is configured to discern the logical value(s) of the data communicated by the TX drivers 100 and 112 over time. The RX drivers 130 and 132 can also be implemented in other ways, including as comparators, slicers, or other types of operational components in some cases.

It can be difficult to design and optimize the RX drivers 130 and 132 to accommodate a relatively wide range of VDDQ_TX and VDDQ_RX supply voltages. The PAM3 voltage levels for signaling will necessarily change or drift with variance in the VDDQ_TX and VDDQ_RX supply voltages. Thus, the RxMSB and RxLSB outputs of the RX drivers 130 and 132 will also vary depending on the VDDQ_TX and VDDQ_RX supply voltages, unless Vref MSB and Vref LSB are also modified to account for any changes in the VDDQ_TX and VDDQ_RX supply voltages.

FIG. 2 illustrates example Vref MSB and Vref LSB reference voltages for the RX drivers 130 and 132 and signal levels for the PAM3 modulation scheme used in the communications interface shown in FIG. 1B. FIG. 2 illustrates voltage or potential along the vertical axis and time along the horizontal axis. The voltage and time scales are representative and not drawn to any particular scale in FIG. 2. In practice, the reference voltages, signal levels for PAM3 (or other forms of) modulation, and the speed of data transfer can vary as compared to those shown in FIG. 2. The Va, Vb, and Vc voltages are representative of levels for signaling (e.g., −1, 0, +1) according to the PAM3 modulation scheme.

The waveform 140 is representative of the voltage potential on the signal trace 10, which is directed by the TX drivers 100 and 112, over time. The waveform 140 is one example of a PAM3 modulated signal waveform according to the embodiments. The voltage of the waveform 140 transitions among the signal voltages Va, Vb, and Vc over time to convey different <MSB, LSB> data states or symbols. With known or predetermined levels for Va, Vb, and Vc, the Vref MSB reference voltage for the RX driver 130 can be selected to be central between the Va and Vb signal voltages. Similarly, the Vref LSB reference voltage for the RX driver 132 can be selected to be central between the Vb and Vc signal voltages. The RX drivers 130 and 132 will then output the difference in voltage between the Vref MSB and Vref LSB reference voltages, respectively, and the voltage on the signal trace 10 (i.e., the waveform 140) over time, as a stage or step in demodulation.

However, as discussed above, the Va, Vb, and Vc voltages will necessarily vary depending on the VDDQ_TX and VDDQ_RX supply voltages at the transmitter side and at the receiver side. Thus, the waveform on the signal trace 10 will exhibit an overall bias potential shift if one or both of the VDDQ_TX and VDDQ_RX supply voltages shifts in voltage. The waveform 142 can be compared against the waveform 140 and depicts an example bias potential shift that occurs when one or both of the VDDQ_TX and VDDQ_RX supply voltages shift (i.e., VDDQ_TX and/or VDDQ_RX increase for the waveform 142 example).

Notably, with the bias potential shift in the waveform 142, the Vref MSB and Vref LSB reference voltages are not as centrally located between the different signaling states for data communication. The RX drivers 130 and 132 will still output the difference in voltage between the Vref MSB and Vref LSB reference voltages and the voltage on the signal trace 10 (i.e., the waveform 142) over time, although the difference voltages will be skewed and not as equally separated for all the different signaling states of the waveform 142. Thus, changes in the VDDQ_TX and VDDQ_RX supply voltages can lead to increased sensitivity to noise, bit errors, and other undesirable conditions.

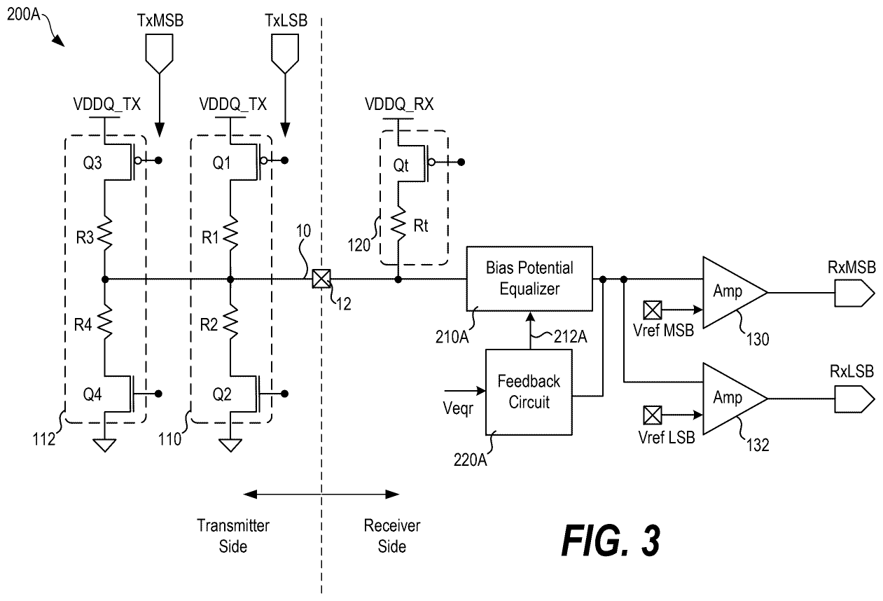

FIG. 3 illustrates a single-ended communications interface 200A (also “interface 200A”) including bias adaptation according to various aspects of the embodiments described herein. The interface 200A is similar to the interface 100A shown in FIG. 1B but also includes a bias potential equalizer 210A (also “potential equalizer 210A”) and a feedback circuit 220A. The bias adaptation achieved by the potential equalizer 210A and the feedback circuit 220A accounts for any shifts in the bias potential due to variations in the VDDQ_TX and VDDQ_RX supply voltages. The potential equalizer 210A and the feedback circuit 220A facilitate the use of a wider range of VDDQ_TX and VDDQ_RX supply voltages. The potential equalizer 210A and the feedback circuit 220A improve the noise sensitivity for the RX drivers 130 and 132, without any need to adjust the Vref MSB and Vref LSB reference voltages. Referring to FIG. 2 as an example, potential equalizer 210A and the feedback circuit 220A are designed to shift the bias potential of the waveform 142 to coincide more closely with the waveform 140, assuming the signal levels and potentials of the waveform 140 are a baseline design choice.

The potential equalizer 210A is configured to alter, modify, or adjust a bias potential on the signal trace 10 based on a control signal 212A from the feedback circuit 220A. In one effect, the potential equalizer 210A imparts an additional impedance at the signal trace 10 node between the TX drivers 110 and 112 and the termination network 120. In another effect, the potential equalizer 210A adjusts the bias potential at the signal trace 10 node between the TX drivers 110 and 112 and the termination network 120. In some embodiments, the potential equalizer 210A is configured to adjust the impedance or bias potential provided at the signal trace 10 over time based on the control signal 212A provided from the feedback circuit 220A.

The potential equalizer 210A can be embodied as a combination of resistors, capacitors, resistor-capacitor (RC) networks, resistor voltage divider networks, biased resistor voltage divider networks, and other circuit components. The network of components of the potential equalizer 210A can be coupled between the signal trace 10 node and ground, at the receiver side.

The feedback circuit 220A is configured to monitor the bias potential on the signal trace 10 and to generate the control signal 212A based on the bias potential. The feedback circuit 220A receives a voltage reference signal, Veqr, as an input according to the example shown in FIG. 3. In one embodiment, the feedback circuit 220A is configured to compare the bias potential on the signal trace 10 with the Veqr voltage reference and generate the control signal 212A based on the comparison. The control signal 212A can be embodied as an analog control signal or a digital control. For example, the control signal 212A can be embodied as an analog voltage-based control signal or an analog current-based control signal. The control signal 212A can also be embodied as a digital control signal in some cases.

The feedback circuit 220A can be embodied as a combination of analog, digital, and analog and digital components. The feedback circuit 220A can include one or more RC filter networks, voltage comparators, current comparators, analog-to-digital converters, digital-to-analog converters, digital to current converters, and other components.

The potential equalizer 210A is configured to adjust the bias potential on the signal trace 10 based on the control signal 212A generated by the feedback circuit 220A. For example, the control signal 212A can be embodied as an analog current control signal. The feedback circuit 220A can generate the control signal 212A as a positive current (e.g., as a source current) when the bias potential on the signal trace 10 is less than the Veqr voltage reference, as one example. The positive control signal 212A current can be larger or smaller depending on the magnitude of the difference between the bias potential on the signal trace 10 and the Veqr voltage reference. The feedback circuit 220A can also generate the control signal 212A as a negative current (e.g., as a sink current) when the bias potential on the signal trace 10 is greater than the Veqr voltage reference. The negative control signal 212A current can be larger or smaller depending on the magnitude of the difference between the bias potential on the signal trace 10 and the Veqr voltage reference.

As one example, if the control signal 212A is embodied as a current control signal, the potential equalizer 210A is configured to increase the bias potential on the signal trace 10 based on a positive or source current. The potential equalizer 210A is also configured to decrease the bias potential on the signal trace 10 based on a negative or sink current. Referring to FIG. 2 as an example, the potential equalizer 210A can shift the bias potential of the waveform 142 to coincide more closely with the waveform 140 based on the control signal 212A from the feedback circuit 220A. The control signal 212A is not limited to a current-based control signal, however. If the control signal 212A is embodied as a voltage-based control signal, the potential equalizer 210A can also be configured to increase or decrease the bias potential on the signal trace 10 based on a positive or negative voltage of the control signal 212A.

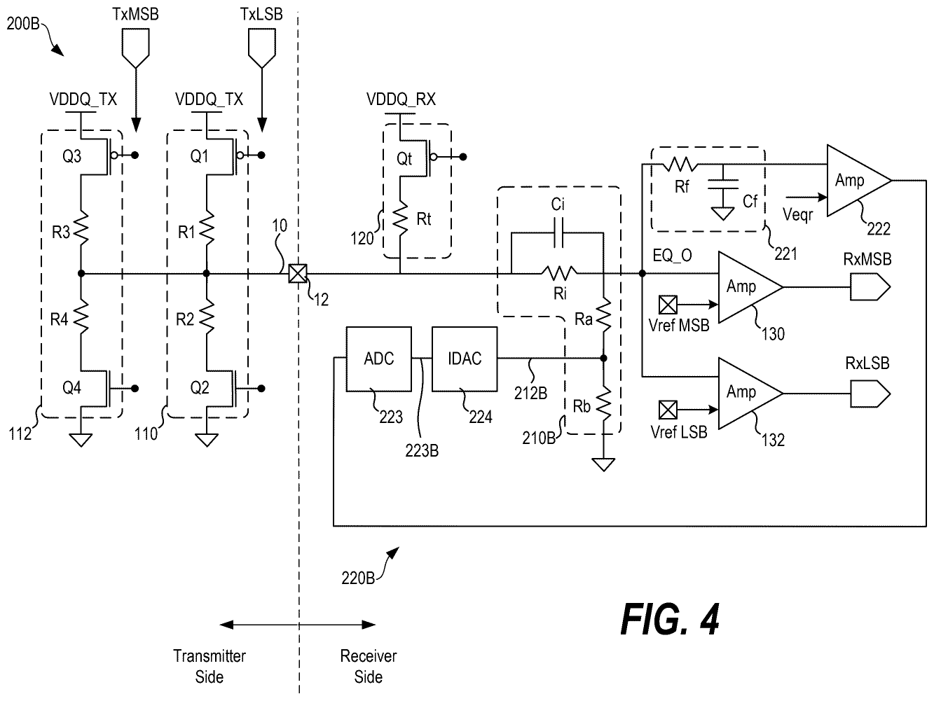

FIG. 4 illustrates a single-ended communications interface 200B (also “interface 200B”) including bias adaptation according to various aspects of the embodiments described herein. The interface 200B is similar to the interface 100A shown in FIG. 3 but also includes a bias potential equalizer 210B (also “potential equalizer 210B”) and a feedback circuit 220B. The potential equalizer 210B in FIG. 4 is one example implementation of the potential equalizer 210A shown in FIG. 3. The feedback circuit 220B in FIG. 4 is also an example implementation of the feedback circuit 220A shown in FIG. 3.

As described below, the bias adaptation achieved by the potential equalizer 210B and the feedback circuit 220B accommodates or adjusts for any shifts in the bias potential due to variations in the VDDQ_TX and VDDQ_RX supply voltages. The potential equalizer 210B and the feedback circuit 220B facilitate the use of a wider range of VDDQ_TX and VDDQ_RX supply voltages. The potential equalizer 210B and the feedback circuit 220B improve the noise sensitivity for the RX drivers 130 and 132, without any need to adjust the Vref MSB and Vref LSB reference voltages. Referring to FIG. 2 as an example, potential equalizer 210B and the feedback circuit 220B are designed to shift the bias potential of the waveform 142 to coincide more closely with the waveform 140, assuming the signal levels and potentials of the waveform 140 are a baseline design choice.

The potential equalizer 210B includes an inline RC network, a resistor voltage divider, and an equalized bias node EQ_O positioned between the inline RC network and the resistor voltage divider. The EQ_O node is coupled as an input to both of the RX drivers 130 and 132. The inline RC network of the potential equalizer 210B includes the capacitor Ci and the resistor Ri. The capacitor Ci and the resistor Ri are coupled in parallel and, together, are coupled between the signal trace 10 and the EQ_O node. The resistor voltage divider of the potential equalizer 210B includes the resistors Ra and Rb.

The feedback circuit 220B includes a feedback loop that extends between the equalized bias node EQ_O and a node positioned between the resistors Ra and Rb of the potential equalizer 210B. The feedback circuit 220B generates the control signal 212B, which is provided as an input to the node positioned between the resistors Ra and Rb of the potential equalizer 210B. The feedback circuit 220B includes an RC filter 221, a difference amplifier 222, an analog-to-digital converter (ADC) 223, and a digital-to-current converter (IDAC) 224. The RC filter 221 is coupled to the EQ_O node as an input. The output of the RC filter 221 is coupled to an input of the difference amplifier 222, and the difference amplifier 222 also receives the Veqr reference voltage as an input. The output of the difference amplifier 222 is provided as an input to the ADC 223. The output of the ADC 223 is provided as an input to the IDAC 224, and the IDAC 224 generates the control signal 212B.

The RC filter 221 includes a resistor Rf and a capacitor Cf. A first end of the resistor Rf is coupled to the EQ_O node, and a second end of the resistor Rf is coupled to an input of the difference amplifier 222. The capacitor Cf is coupled between the second end of the resistor Rf and ground. The RC filter 221 is arranged as a low pass filter in the example shown. The resistance of the resistor Rf and the capacitance of the capacitor Cf can be selected to pass the bias potential at the EQ_O node to the difference amplifier 222. The difference amplifier 222 also receives the Veqr reference voltage as an input.

The difference amplifier 222 compares the bias voltage output from the RC filter 221 with the Veqr reference voltage and outputs a difference voltage potential based on the difference between them. The Veqr reference voltage can be selected based on the expected ranges of the VDDQ_TX and VDDQ_RX supply voltages. As one example, if the VDDQ_TX and VDDQ_RX supply voltages are expected to range from about 1V to 1.6V, then the bias voltage at the EQ_O node can be expected to range from about 0.525V to 0.84V. The Veqr reference voltage can then be selected centrally between 0.525V and 0.84V, such as at about 0.65V.

The output of the difference amplifier 222 is provided as an input to the ADC 223. The ADC 223 can convert the analog difference voltage from the difference amplifier 222 to a digital difference value 223B. The ADC 223 can be embodied as an 8-bit analog-to-digital converter, for example, although other types of analog-to-digital converters can be relied upon. The ADC 223 is configured to generate a digital difference value 223B based on the difference voltage output by the difference amplifier 222. The digital difference value 223B from the ADC 223 is provided as an input to the IDAC 224.

The IDAC 224 can be embodied as an 8-bit current-output digital-to-analog converter, although other types of converters can be relied upon. The output of the IDAC 224 is the control signal 212B, which is a current, and the control signal 212B is injected into the node between the Ra and Rb resistors of the potential equalizer 210B. The IDAC 224 is capable of either sourcing a current or sinking a current. More particularly, because the output of the IDAC 224 is coupled to the node between the Ra and Rb resistors in the potential equalizer 210B, the IDAC 224 can either source current to the node or sink current from the node. When a current is injected or sourced to the node between the Ra and Rb resistors by the IDAC 224, the bias potential at the node and at the EQ_O node will increase. Alternatively, when a current is sunk from the node between the Ra and Rb resistors by the IDAC 224, the bias potential at the node and at the EQ_O node will decrease.

The potential equalizer 210B is thus configured to adjust the bias potential at the EQ_O node based on the control signal 212B from the feedback circuit 220B. Referring to FIG. 2 as an example, the potential equalizer 210B can shift the bias potential of the waveform 142 to coincide more closely with the waveform 140 based on the control signal 212B from the feedback circuit 220B. The ADC 223, IDAC 224, and resistances of Ra and Rb can be selected to provide sufficient granularity and variation for bias potential feedback control. The ADC 223 and IDAC 224 can offer hundreds of steps of feedback control, and the total number of steps can be tailored based on design needs. The IDAC 224 can be selected for current control per step in the μA or fraction of μA range, and larger or smaller steps can be relied upon. If Ra is selected at 2 kΩ and Rb is selected at 5 kΩ, as an example, then the resulting change in the bias potential at the EQ_O node can be in the range of tens or hundreds of mV per step of the IDAC 224. However, the ADC 223, IDAC 224, and resistances of Ra and Rb can be selected for other ranges or spreads of bias potential feedback control.

Overall, the potential equalizer 210A and the feedback circuit 220A help to bias-align the received data signals with the reference potentials for data decisions without degrading noise sensitivity for the RX drivers 130 and 132 through the adjustment or adaptation of the bias potential at the EQ_O node. The potential equalizer 210A and the feedback circuit 220A facilitate the use of the same Vref MSB and Vref LSB reference voltages even over a range of different VDDQ_TX and VDDQ_RX supply voltages in single-ended signaling interfaces, such as in the interface 200B. The concepts of bias adaptation and voltage potential equalization can be extended to single-ended interfaces using higher-order and lower-order PAM modulation techniques (e.g., including the interface 100A shown in FIG. 1A). The concepts can also be extended to single-ended interfaces using other modulation techniques beyond PAM modulation in some cases.

The feedback circuit 220B can be implemented in alternative ways with alternative components in some cases. As one example, the feedback circuit 220B can operate with a clocking or synchronizing signal in a digital format. The difference amplifier 222 can be embodied as a comparator and output one of two logical output voltages depending on a comparison between the bias potential at the EQ_O node and the Veqr reference voltage in that case. Further, the ADC 223 can be replaced with a counter that increments or decrements according to the logical output of the comparator based on a clocking signal. The counter can be an 8-bit, for example, and the output of the counter can be provided to the IDAC 224. These and other variations are within the scope of the embodiments.

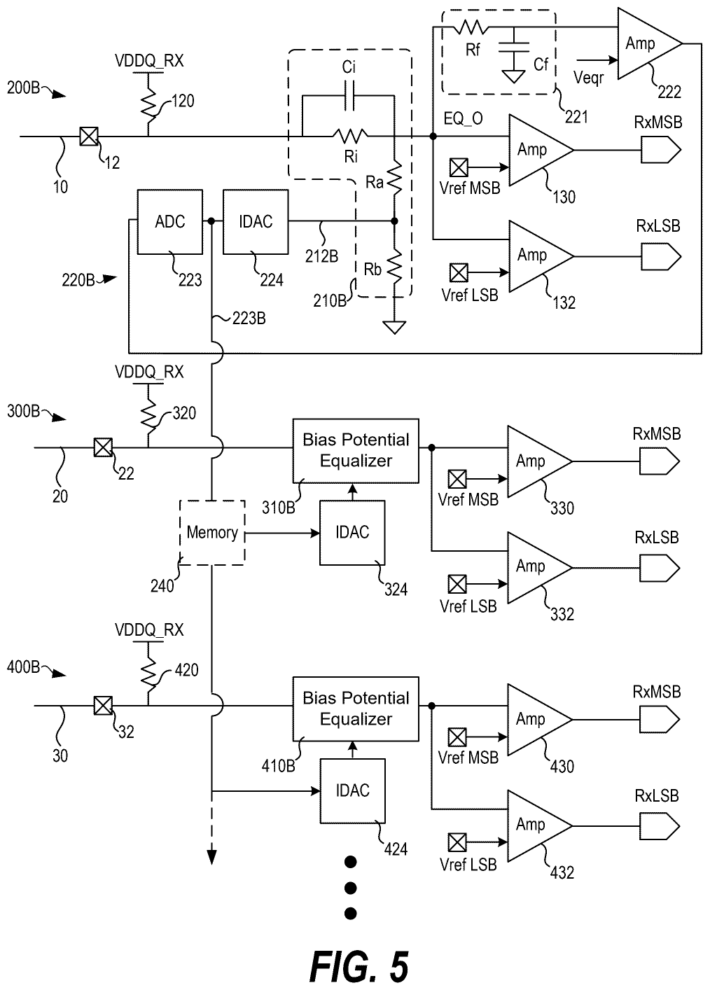

In other aspects of the embodiments, the feedback circuit 220B in the interface 200B can be relied upon to adjust or adapt biasing in other single-ended interfaces. FIG. 5 illustrates the interface 200B along with additional single-ended communications interfaces 300B and 400B. The interfaces 200B, 300B, and 400B can be implemented together as a number of single-ended interfaces on an IC device. FIG. 5 is a representative and, in practice, additional single-ended communications interfaces can be relied upon to form a data bus, for example.

Each of the single-ended communications interfaces 300B and 400B is similar to the interface 200B. The interface 300B includes a termination network 320, the bias potential equalizer 310B, the RX drivers 330 and 332, and the IDAC 324. The interface 300B is implemented over the signal trace 20, which extends from a transmitter side to the receiver side and across the terminal 22. The interface 400B includes a termination network 420, the bias potential equalizer 410B, the RX drivers 430 and 432, and the IDAC 424. The interface 400B is implemented over the signal trace 40, which extends from a transmitter side to the receiver side and across the terminal 32. The termination networks 320 and 420 are similar to the termination network 120. The bias potential equalizers 310B and 410B are also similar to the bias potential equalizer 210B in both structure and function.

As shown in FIG. 5, the interfaces 300B and 400B do not include full feedback circuits. That is, the interface 200B includes the feedback circuit 220B, but the interfaces 300B and 400B do not include full feedback circuits. Instead, the digital difference value 223B output by the ADC 223 of the feedback circuit 220B is extended and mirrored to the IDAC circuits 324 and 424 in the interfaces 300B and 400B. If needed, the memory 240 can be relied upon to store the digital difference value 223B output by the ADC 223. From the memory 240, the digital difference value 223B can be extended and mirrored to the IDAC circuits 324 and 424 in the interfaces 300B and 400B, among other IDAC circuits in other interfaces.

In some cases, the digital difference value 223B can be determined in a first, startup or training phase of operation for the receiver circuit shown in FIG. 5. Training data, such as PAM3-modulated pseudorandom binary sequence (PRBS) data, can be communicated over the interface 200B during the training phase of operation. The bias potential equalizer 210B and the feedback circuit 220B can operate to adjust the bias potential at the EQ_O node, as needed, based on the VDDQ_TX and VDDQ_RX supply voltages used during the training phase. In other words, the bias potential equalizer 210B and the feedback circuit 220B can operate to identify and settle on the digital difference value 223B or within a range of a static digital difference value 223B.

The digital difference value 223B can be settled and established during the training phase of operation, and the digital difference value 223B can be stored in the memory 240. From the memory 240, the digital difference value 223B can be provided, extended, or mirrored to the IDAC circuits 324 and 424 in the interfaces 300B and 400B, among other IDAC circuits in other interfaces. Thus, the memory 240 is configured to store the digital difference value 223B and also to provide it to the interfaces 300B and 400B. In some cases, the memory 240 can be omitted, and the digital difference value 223B can be provided directly from the ADC 223 to the IDAC circuits 224, 324, 424 in the interfaces 200B, 300B, and 400B. The digital difference value 223B can be updated or re-established during operation, as needed, from time to time or during any suitable schedule. Overall, extending the output by the ADC 223 of the feedback circuit 220B to other interfaces 300B and 400B reduces circuit complexity and costs.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed.

The terms “comprising,” “including,” “having,” and the like are synonymous, are used in an open-ended fashion, and do not exclude additional elements, features, acts, operations, and so forth. Also, the term “or” is used in its inclusive sense, and not in its exclusive sense, so that when used, for example, to connect a list of elements, the term “or” means one, some, or all of the elements in the list.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Combinatorial language, such as “at least one of X, Y, and Z” or “at least one of X, Y, or Z,” unless indicated otherwise, is used in general to identify one, a combination of any two, or all three (or more if a larger group is identified) thereof, such as X and only X, Y and only Y, and Z and only Z, the combinations of X and Y, X and Z, and Y and Z, and all of X, Y, and Z. Such combinatorial language is not generally intended to, and unless specified does not, identify or require at least one of X, at least one of Y, and at least one of Z to be included.

The terms “about” and “substantially,” unless otherwise defined herein to be associated with a particular range, percentage, or metric of deviation, account for at least some manufacturing tolerances between a theoretical design and a manufactured product or assembly. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A receiver circuit with adaptive biasing comprising:
an on-die termination network coupled to a single-ended receiver input;
a potential equalizer coupled to the single-ended receiver input and the on-die termination network, the potential equalizer comprising a biased voltage divider and an equalized bias node;
a receive driver coupled to the equalized bias node; and
a feedback circuit loop coupled between the equalized bias node and a node in the biased voltage divider.

2. The receiver circuit according to claim 1, wherein:
the feedback circuit loop generates a current control signal; and
the current control signal is injected into a node of the biased voltage divider.

3. The receiver circuit according to claim 2, wherein the feedback circuit loop adjusts a bias voltage at the equalized bias node based on the current control signal.

4. The receiver circuit according to claim 1, wherein:
the potential equalizer further comprises an inline resistor-capacitor (RC) network coupled to the single-ended receiver input; and
the equalized bias node is positioned between the RC network and the biased voltage divider.

5. The receiver circuit according to claim 1, wherein the feedback circuit loop comprises a difference amplifier, an analog-to-digital converter, and a digital-to-current converter.

6. The receiver circuit according to claim 5, wherein the feedback circuit loop further comprises a filter between the equalized bias node and the difference amplifier.

7. The receiver circuit according to claim 5, wherein the difference amplifier outputs a difference voltage based on a difference between a reference voltage and a bias voltage at the equalized bias node.

8. The receiver circuit according to claim 7, wherein the analog-to-digital converter converts the difference voltage from the difference amplifier to a digital difference value.

9. The receiver circuit according to claim 8, wherein:
the digital-to-current converter converts the digital difference value to a current control signal; and
the current control signal is injected into a node of the biased voltage divider.

10. The receiver circuit according to claim 8, further comprising:
a second single-ended receiver input;
a second potential equalizer coupled to the second single-ended receiver input, second the potential equalizer comprising a second biased voltage divider and a second equalized bias node;
a second digital-to-current converter; and
a memory to store the digital difference value and provide the digital difference value to the second digital-to-current converter for control of the second equalized bias node.

11. A receiver circuit comprising:
a receiver input;
a potential equalizer coupled to the receiver input, the potential equalizer comprising a biased voltage divider and an equalized bias node; and
a feedback circuit loop coupled between the equalized bias node and a node in the biased voltage divider.

12. The receiver circuit according to claim 11, wherein:
the feedback circuit loop generates a current control signal; and
the current control signal is injected into a node of the biased voltage divider.

13. The receiver circuit according to claim 12, wherein the feedback circuit loop adjusts a bias voltage at the equalized bias node based on the current control signal.

14. The receiver circuit according to claim 11, wherein:
the potential equalizer further comprises an inline resistor-capacitor (RC) network coupled to the receiver input; and
the equalized bias node is positioned between the RC network and the biased voltage divider.

15. The receiver circuit according to claim 11, wherein the feedback circuit loop comprises a difference amplifier, an analog-to-digital converter, and a digital-to-current converter.

16. The receiver circuit according to claim 15, wherein the feedback circuit loop further comprises a filter between the equalized bias node and the difference amplifier.

17. The receiver circuit according to claim 15, wherein the difference amplifier outputs a difference voltage based on a difference between a reference voltage and a bias voltage at the equalized bias node.

18. The receiver circuit according to claim 17, wherein the analog-to-digital converter converts the difference voltage from the difference amplifier to a digital difference value.

19. The receiver circuit according to claim 18, wherein:
the digital-to-current converter converts the digital difference value to a current control signal; and
the current control signal is injected into a node of the biased voltage divider.

20. The receiver circuit according to claim 18, further comprising:
a second single-ended receiver input;
a second potential equalizer coupled to the second single-ended receiver input, second the potential equalizer comprising a second biased voltage divider and a second equalized bias node;
a second digital-to-current converter; and
a memory to store the digital difference value and provide the digital difference value to the second digital-to-current converter for control of the second equalized bias node.
